(19) United States
(12) Patent Application Publication
(10) Pub. No.: US 2020/0333706 A1
(43) Pub. Date: Oct. 22, 2020

(54) PATTERNED SUBSTRATE-PRODUCING METHOD

(71) Applicant: JSR CORPORATION, Tokyo (JP)

(72) Inventors: Ryuichi SERIZAWA, Tokyo (JP); Nozomi SATOU, Tokyo (JP); Yuusuke OOTSUBO, Tokyo (JP)

(73) Assignee: JSR CORPORATION, Tokyo (JP)

(21) Appl. No.: 16/923,140

(22) Filed: Jul. 8, 2020

Related U.S. Application Data
(63) Continuation of application No. PCT/JP2018/046876, filed on Dec. 19, 2018.

(30) Foreign Application Priority Data
Jan. 9, 2018 (JP) 2018-001466

(51) Int. Cl. G03F 7/00; G03F 7/40; G03F 7/20; G03F 7/09; G03F 7/004

(52) U.S. Cl. CPC G03F 7/0035; G03F 7/40; G03F 7/0043; G03F 7/09; G03F 7/7085

(57) ABSTRACT

A patterned substrate-producing method includes applying a surface treatment agent on a surface layer of a substrate. The surface layer includes at least one metal element. A resist composition is applied on a surface of the surface layer to provide a resist film on the surface. The resist film is exposed to an extreme ultraviolet ray or an electron beam. The resist film exposed is developed to form a resist pattern. The substrate is etched using the resist pattern as a mask. The surface treatment agent includes: a polymer including a group including a polar group at at least one end of a main chain of the polymer; and a solvent.

### CROSS-REFERENCE TO RELATED APPLICATIONS

The present application is a continuation application of International Application No. PCT/JP2018/046876, filed Dec. 19, 2018, which claims priority to Japanese Patent Application No. 2018-001466, filed Jan. 9, 2018. The contents of these applications are incorporated herein by reference in their entirety.

### BACKGROUND OF THE INVENTION

### Field of the Invention

The present invention relates to a patterned substrate-producing method.

### Description of the Related Art

In pattern formation of semiconductor elements and the like, resist processes are often employed in which a resist film laminated on a base with an underlayer film or the like therebetween is exposed and developed, and etching is carried out using a resultant resist pattern as a mask (see Japanese Unexamined Patent Application, Publication No. 2004-310019 and PCT International Publication No. 2012/039337).

In recent years, highly enhanced integration of semiconductor devices has advanced further, and exposure light to be used tends to have a shorter wavelength, as from a KrF excimer laser beam (248 nm) or an ArF excimer laser beam (193 nm) to an extreme ultraviolet ray (13.5 nm; EUV). In this context, the output of an EUV exposure light source is insufficient. Therefore, EUV lithography, in which the resist film is exposed to an EUV, requires formation of a resist pattern in a highly sensitive manner. In other words, it is necessary to enable forming a favorable resist pattern at a low-energy exposure dose.

### SUMMARY OF THE INVENTION

According to an aspect of the present invention, a patterned substrate-producing method includes applying a surface treatment agent on a surface layer of a substrate. The surface layer includes at least one metal element. A resist composition is applied on a surface of the surface layer to provide a resist film on the surface. The resist film is exposed to an extreme ultraviolet ray or an electron beam. The resist film exposed is developed to form a resist pattern. The substrate is etched using the resist pattern as a mask. The surface treatment agent includes: a polymer including a group including a polar group at at least one end of a main chain of the polymer; and a solvent.

### DESCRIPTION OF EMBODIMENTS

According to an embodiment of the invention, a patterned substrate-producing method includes: applying a surface treatment agent on a surface of a substrate containing a metal element in at least one surface layer, the surface containing the metal element; applying a resist composition on a face on which the surface treatment agent has been applied; exposing to an extreme ultraviolet ray or an electron beam, a resist film formed by the applying of the resist composition; developing the resist film exposed; and etching the substrate using as a mask a resist pattern formed by the developing, wherein the surface treatment agent contains a polymer that includes a group having a polar group at at least one end of a main chain, and a solvent.

The patterned substrate-producing method of the embodiment of the present invention enables extreme ultraviolet lithography or electron beam lithography to be carried out in a highly sensitive manner, a resist pattern superior in resolution and the collapse-inhibiting property to be obtained, and in turn a favorable substrate pattern to be obtained. Accordingly, the patterned substrate-producing method can be suitably used for extreme ultraviolet lithography or electron beam lithography, as well as for manufacture of semiconductor devices, for which microfabrication is expected to progress further hereafter, and the like.

Hereinafter, a patterned substrate-producing method according to an embodiment of the present invention will be described.

### Patterned Substrate-Producing Method

The patterned substrate-producing method (hereinafter, may be also referred to as “substrate-producing method”) includes the steps of: preparing a substrate containing a metal element in at least one surface (hereinafter, may be also referred to as “substrate-preparing step”); applying a surface treatment agent (hereinafter, may be also referred to as “(S) surface treatment agent” or “surface treatment agent (S)”) on the at least one surface of the substrate, the at least one surface containing the metal element (hereinafter, may be also referred to as “surface treatment agent-applying step”); applying a resist composition on a face on which the surface treatment agent has been applied (hereinafter, may be also referred to as “resist composition-applying step”); exposing to an extreme ultraviolet ray or an electron beam, a resist film formed by the applying of the resist composition (hereinafter, may be also referred to as “exposing step”); developing the resist film exposed (hereinafter, may be also referred to as “developing step”); and etching the substrate using as a mask a resist pattern formed by the developing (hereinafter, may be also referred to as “etching step”), wherein the surface treatment agent (S) contains a polymer (hereinafter, may be also referred to as “(C) polymer” or “polymer (C)”) that includes a group having a polar group at at least one end of a main chain, and a solvent (hereinafter, may be also referred to as “(D) solvent” or “solvent (D)”).

The substrate-producing method including the above steps enables extreme ultraviolet lithography or electron beam lithography to be carried out in a highly sensitive manner, a resist pattern superior in resolution and a collapse-inhibiting property to be formed, and in turn a favorable substrate pattern to be obtained. Although not necessarily clarified and without wishing to be bound by any theory, the reason for achieving the effects described above due to the substrate-producing method having the constitution described above may be supposed as in the following, for example. To explain specifically, it is considered that using the substrate containing the metal element in the at least one surface, the EUV ray or the electron beam which is radiated in extreme ultraviolet lithography or electron beam lithography, respectively, is absorbed by the metal element in the at least one surface of the substrate; accordingly, secondary electrons and the like are generated, and the secondary electrons impart sensitivity to the resist film. It is considered that according to the substrate-producing method, the surface treatment agent containing the polymer having, at the end of the main chain, the polar group that is able to interact with the metal element in the at least one surface and having the specific structure described above, is applied on the at least one surface of the substrate, whereby the hydrophilicity of the substrate surface can be appropriately reduced while maintaining electronic states, coordination states, and the like of metal atoms in the substrate surface to some extent; accordingly, the resolution and the collapse-inhibiting property of the resist pattern to be formed can be increased while improving the sensitivity to the extreme ultraviolet ray or the electron beam in the exposing, and in turn a favorable substrate pattern can be obtained.

Before the resist composition-applying step, the substrate-producing method may further include treating the face on which the surface treatment agent has been applied (hereinafter, may be also referred to as “treatment step”) with one, or two or more of: exposure to an ultraviolet ray, exposure to oxygen plasma, contact with water, contact with an alkali, contact with an acid, contact with hydrogen peroxide, and contact with ozone. Hereinafter, each step will be described.

Substrate-Preparing Step

In this step, a substrate (hereinafter, may be also referred to as “substrate (P)”) containing a metal element in at least one surface layer is prepared. The “surface layer” as referred to herein means a region of up to 5 nm in depth from a surface of the substrate.

The metal element (hereinafter, may be also referred to as “metal element (a)”) contained in the at least one surface layer of the substrate (P) is exemplified by a metal element belonging to period 3 to period 7 of group 3 to group 15 in periodic table, and the like. It is to be noted that the metal element (a) does not include metalloid elements such as boron, silicon, arsenic, and the like.

Examples of the metal element (a) belonging to group 3 include scandium, yttrium, lanthanum, cerium, and the like;

examples of the metal element (a) belonging to group 4 include titanium, zirconium, hafnium, and the like;

examples of the metal element (a) belonging to group 5 include vanadium, niobium, tantalum, and the like;

examples of the metal element (a) belonging to group 6 include chromium, molybdenum, tungsten, and the like; examples of the metal element (a) belonging to group 7 include manganese, rhenium, and the like;

examples of the metal element (a) belonging to group 8 include iron, ruthenium, osmium, and the like;

examples of the metal element (a) belonging to group 9 include cobalt, rhodium, iridium, and the like;

examples of the metal element (a) belonging to group 10 include nickel, palladium, platinum, and the like;

examples of the metal element (a) belonging to group 11 include copper, silver, gold, and the like;

examples of the metal element (a) belonging to group 12 include zinc, cadmium, mercury, and the like;

examples of the metal element (a) belonging to group 13 include aluminum, gallium, indium, and the like;

examples of the metal element (a) belonging to group 14 include germanium, tin, lead, and the like; and

examples of the metal element (a) belonging to group 15 include antimony, bismuth, and the like.

The metal element (a) is preferably a metal element belonging to period 4 to period 7 of group 3 to group 15, more preferably a metal element belonging to period 4 to period 7 of group 4 to group 6, still more preferably the metal element belonging to group 4, and particularly preferably titanium or zirconium.

The substrate (P) is exemplified by a substrate having a layer (hereinafter, may be also referred to as “metal-containing layer (T)”) containing the metal element (a) on at least an upper face of the base, a metal-containing substrate, and the like.

The base is exemplified by a base having an insulating film of silicon oxide, silicon nitride, silicon oxynitride, polysiloxane, or the like; a resin base; and the like. For example, a wafer or the like coated with a low-dielectric insulating film formed from “Black Diamond” available from AMAT, “SiLK” available from Dow Chemical, “LKD5109” available from JSR Corporation, or the like may be used. As the base, a patterned base with wiring grooves (trenches), plug grooves (vias), or the like may be used.

Organic Underlayer Film

In the substrate (P), an organic underlayer film may be provided between the base and the metal-containing layer (T). In other words, the substrate may include the base, the organic underlayer film formed directly or indirectly on at least the upper face of the base, and the metal-containing layer formed directly or indirectly on an upper face of the organic underlayer film.

The organic underlayer film differs from the metal-containing layer (T). The organic underlayer film serves in further supplementing a function exhibited by the metal-containing layer (T) and/or the resist film in the substrate-producing method, as well as in imparting a necessary specific function for attaining a function not exhibited by the metal-containing layer (T) and/or the resist film (for example, an antireflective property, coating film flatness, or high etching resistance to a fluorine-based gas).

The organic underlayer film is exemplified by an antireflective film and the like. An exemplary antireflective film-forming composition may include “NFC HM8006,” available from JSR Corporation, and the like.

The organic underlayer film may be formed by applying an organic-underlayer film-forming composition through spin coating or the like to form a coating film, followed by heating.

Metal-Containing Layer

The metal-containing layer (T) is a layer containing the metal element (a). Examples of a procedure for forming the metal-containing layer (T) include a procedure using a metal-containing composition (hereinafter, may be also referred to as “metal-containing composition (X)”), a procedure employing chemical vapor deposition (CVD), physical vapor deposition (PVD), or the like, and the like.

Metal-Containing Composition

The metal-containing composition (X) is exemplified by a composition containing a compound (hereinafter, may be also referred to as “(A) compound” or “compound (A)”) having a metal-oxygen covalent bond, and a solvent (hereinafter, may be also referred to as “(B) solvent” or “solvent (B)”); and the like.

The compound (A) may contain element(s) (hereinafter, may be also referred to as “other element(s)”) other than the metal element (a) and oxygen. Examples of the other element(s) include: metalloid elements such as boron and silicon; nonmetal elements such as carbon, hydrogen, nitrogen, phosphorus, sulfur, and halogens; and the like. Of these, silicon, carbon, and/or hydrogen are/is preferred.

The lower limit of a percentage content of atoms of the metal element (a) in the compound (A) is preferably 1% by mass, more preferably 5% by mass, and still more preferably 10% by mass. The upper limit of the percentage content is preferably 50% by mass. The percentage content of the atoms of the metal element (a) may be determined by measurement in which a differential thermal balance (TG/DTA) is used.

The compound (A) is exemplified by a polynuclear complex having a bond of metal-oxygen-metal, and the like. The “polynuclear complex” as referred to herein means a complex having a plurality of metal atoms. Such a polynuclear complex can be synthesized by, for example, hydrolytic condensation of a metal-containing compound having a hydrolyzable group, as described later.

In a case in which the compound (A) is the polynuclear complex, the lower limit of a polystyrene-equivalent weight average molecular weight (Mw) of the compound (A) as determined by gel permeation chromatography (GPC) is preferably 1,000, more preferably 1,500, and still more preferably 2,000. The upper limit of the Mw is preferably 30,000, more preferably 20,000, and still more preferably 15,000.

Herein, the Mw of the compound (A) is a value determined by gel permeation chromatography (detector: differential refractometer) using GPC columns (“AWM-H”×2; “AW-H”×1; and “AW2500”×2, available from Tosoh Corporation) under an analytical condition involving a flow rate of 0.3 mL/min, an elution solvent of a mixture prepared by adding LiBr (30 mM) and citric acid (30 mM) to N,N′-dimethylacetamide, and a column temperature of 40° C., with mono-dispersed polystyrene as a standard.

The lower limit of a percentage content of the compound (A) in the metal-containing composition (X) with respect to all components other than the solvent (B) is preferably 70% by mass, more preferably 80% by mass, and still more preferably 90% by mass. The upper limit of the percentage content may be 100% by mass. When the percentage content of the compound (A) falls within the above range, coating characteristics of the metal-containing composition (X) can be further improved. The metal-containing composition (X) may contain one, or two or more types of the compound (A).

The compound (A) used may be a commercially available metal compound, or may be synthesized by, for example, a procedure of carrying out a hydrolytic condensation reaction by using a metal-containing compound having a hydrolyzable group (hereinafter, may be also referred to as “(b) metal-containing compound” or “metal-containing compound (b)”), or the like. In other words, the compound (A) may be derived from the metal-containing compound (b). The “hydrolytic condensation reaction” as referred to herein means a reaction in which a hydrolyzable group included in the metal-containing compound (b) is hydrolyzed to give —OH, and two —OHs thus obtained undergo dehydrative condensation to form —O—.

The metal-containing compound (b) may be: a metal compound having a hydrolyzable group (hereinafter, may be also referred to as “metal compound (I)”); a hydrolysis product of the metal compound (I); a hydrolytic condensation product of the metal compound (I); or a combination thereof. The metal compound (I) may be used either alone of one type, or in a combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, an n-propoxy group, an i-propoxy group, a butoxy group, and the like.

Examples of the acyloxy group include an acetoxy group, an ethylyloxy group, a propionyloxy group, a butyryloxy group, a t-butyryloxy group, a t-amylyloxy group, an n-hexanecarbonyloxy group, an n-octanecarbonyloxy group, and the like.

As the hydrolyzable group, the alkoxy group is preferred, and an i-propoxy group or a butoxy group is more preferred.

In a case in which the metal-containing compound (b) is a hydrolytic condensation product of the metal compound (I), the hydrolytic condensation product of the metal compound (I) may be a hydrolytic condensation product of the metal compound (I) containing the metal element (a) with a compound containing a metalloid element, within a range not leading to impairment of the effects of the present invention.

The metal compound (I) is exemplified by compounds represented by the following formula (1) (hereinafter, may be also referred to as a “metal compound (I-1)”), and the like.

LₐMY_{b} (1)

In the above formula (1), M represents a metal atom; L represents a ligand; “a” is an integer of 0 to 6, wherein in a case in which “a” is no less than 2, a plurality of Ls are identical or different; Y represents a hydrolyzable group selected from a halogen atom, an alkoxy group, or an acyloxy group; and b is an integer of 2 to 6, wherein a plurality of Ys are identical or different, and L is a ligand not falling under the category of Y.

The metal atom represented by M may be exemplified by atoms similar to those exemplified as the atom of the metal element (a) contained in the at least one surface layer of the substrate (P), and the like.

The ligand represented by L is exemplified by a monodentate ligand and a polydentate ligand.

Exemplary monodentate ligands include a hydroxo ligand, a carboxy ligand, an amido ligand, an amine ligand, an ammonia ligand, an olefin ligand, and the like.

Exemplary polydentate ligands include a ligand derived from a hydroxy acid ester, a ligand derived from a β-diketone, a ligand derived from a β-keto ester, a ligand derived from an α,α-dicarboxylic acid ester, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the α,α-dicarboxylic acid ester include malonic acid diesters, α-alkyl-substituted malonic acid diesters, α-cycloalkyl-substituted malonic acid diesters, α-aryl-substituted malonic acid diesters, and the like.

In the formula (1), “a” is preferably 0 to 3, more preferably 0 to 2, still more preferably 1 or 2, and particularly preferably 2. When “a” is a value described above, stability of the compound (A) can be appropriately improved.

The hydrolyzable group which may be represented by Y is exemplified by groups similar to those exemplified as the hydrolyzable group in the metal-containing compound (b), and the like.

In the above formula (1), b is preferably 2 to 4, more preferably 2 or 3, and still more preferably 2. When b is a value described above, the molecular weight of the compound (A) that is a hydrolytic condensation product can be appropriately increased.

Examples of the metal-containing compound (b) include:

titanium-containing compounds such as diisopropoxybis(2,4-pentanedionato) titanium(IV), tetra-n-butoxy titanium(IV), tetra-n-propoxy titanium(IV), titanium(IV) tri-n-butoxymonostearate, a titanium(IV) butoxide oligomer, aminopropyltrimethoxy titanium(IV), triethoxymono(2,4-pentanedionato) titanium(IV), tri-n-propoxymono(2,4-pentanedionato) titanium(IV), triisopropoxymono(2,4-pentanedionato) titanium, and di-n-butoxybis(2,4-pentanedionato) titanium(IV);

zirconium-containing compounds such as dibutoxybis(ethylacetoacetate) zirconium(IV), di-n-butoxybis(2,4-pentanedionato) zirconium(IV), tetra-n-butoxy zirconium(IV), tetra-n-propoxy zirconium(IV), tetraisopropoxy zirconium(IV), aminopropyltriethoxy zirconium(IV), 2-(3,4-epoxycyclohexyl)ethyltrimethoxy zirconium(IV), γ-glycidoxypropyltrimethoxy zirconium(IV), 3-isocyanopropyltrimethoxy zirconium(IV), triethoxymono(2,4-pentanedionato) zirconium(IV), tri-n-propoxymono(2,4-pentanedionato) zirconium(IV), triisopropoxymono(2,4-pentanedionato) zirconium(IV), tri(3-methacryloxypropyl)methoxy zirconium(IV), and tri(3-acryloxypropyl)methoxy zirconium(IV);

hafnium-containing compounds such as diisopropoxybis(2,4-pentanedionato) hafnium(IV), tetrabutoxy hafnium(IV), tetraisopropoxy hafnium(IV), tetraethoxy hafnium(IV), and dichlorobis(cyclopentadienyl) hafnium(IV);

tantalum-containing compounds such as tetrabutoxy tantalum(IV), pentabutoxy tantalum(V), and pentaethoxy tantalum(V);

tungsten-containing compounds such as tetrabutoxy tungsten(IV), pentabutoxy tungsten(V), pentamethoxy tungsten(V), hexabutoxy tungsten(VI), hexaethoxy tungsten(VI), and dichlorobis(cyclopentadienyl)tungsten(IV);

iron-containing compounds such as iron chloride(III);

ruthenium-containing compounds such as diacetato[(S)-(−)-2,2′-bis(diphenylphosphino)-1,1′-binaphthyl] ruthenium(II);

cobalt-containing compounds such as dichloro[ethylenebis(diphenylphosphine)] cobalt(II);

zinc-containing compounds such as diisopropoxy zinc(II) and zinc(II) acetate;

aluminum-containing compounds such as diisopropoxyethylacetoacetate aluminum(III), and aluminum(III) acetate;

indium-containing compounds such as indium(III) acetate and triisopropoxy indium(III);

tin-containing compounds such as tetraethyldiacetoxy stannoxane, tetrabutoxy tin(IV), tetraisopropoxy tin(IV), and t-butyltris(diethylamide) tin(IV); and

germanium-containing compounds such as tetraisopropoxy germanium(IV).

Upon a synthesis reaction of the compound (A), in addition to the metal compound (I), a compound that can be the monodentate ligand or the polydentate ligand, a compound that can be a bridging ligand, etc. may also be added. The compound that can be the bridging ligand is exemplified by a compound having a hydroxy group, an isocyanate group, an amino group, an ester group, or an amide group each in a plurality of number, and the like.

A procedure for carrying out the hydrolytic condensation reaction using the metal-containing compound (b) may be exemplified by: a procedure of causing a hydrolytic condensation reaction of the metal-containing compound (b) in a solvent containing water; and the like. In this case, another compound having a hydrolyzable group may be added as needed.

The solvent (B) is not particularly limited as long as it is capable of dissolving or dispersing the compound (A) and other component(s) which may be contained as needed. The solvent (B) is exemplified by alcohol solvents, ketone solvents, ether solvents, ester solvents, nitrogen-containing solvents, water, and the like. The solvent (B) may be used either alone of one type, or in a combination of two or more types thereof.

Of these, the ether solvents, the ester solvents, and/or water are/is preferred, and ester solvents or ether solvents each having a glycol structure are more preferred.

Examples of the ether solvents or the ester solvents each having a glycol structure include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like.

The metal-containing composition (X) may contain, as the other component(s) apart from the compound (A) and the solvent (B), for example, an acid generating agent, a surfactant, and/or the like.

The acid generating agent is a compound that generates an acid due to irradiation with ultraviolet light and/or heating. The acid generating agent may be used either alone of one type, or in a combination of two or more types thereof.

Exemplary acid generating agents include onium salt compounds, N-sulfonyloxyimide compounds, and the like.

Preparation Procedure of Metal-Containing Composition

A preparation procedure of the metal-containing composition (X) is not particularly limited; it may be prepared by, for example, mixing at a predetermined ratio the compound (A), the solvent (B), and the other component(s) which may be contained as needed, and preferably filtering a thus resulting mixed solution through a filter having a pore size of no greater than 0.2 μm.

The lower limit of a solid content concentration of the metal-containing composition (X) is preferably 0.01% by mass, more preferably 0.05% by mass, still more preferably 0.1% by mass, and particularly preferably 0.2% by mass. The upper limit of the solid content concentration is preferably 20% by mass, more preferably 10% by mass, still more preferably 5% by mass, and particularly preferably 3% by mass. The “solid content concentration” of the metal-containing composition (X) as referred to herein means a value (% by mass) as determined by: baking the metal-containing composition (X) at 250° C. for 30 min; measuring a mass of the solid content in the metal-containing composition (X); and dividing the mass of the solid content by the mass of the metal-containing composition (X).

The metal-containing layer (T) may be formed by: applying the metal-containing composition (X) on a surface of the base, or of another underlayer film such as the organic underlayer film, etc. to form a coating film; and subjecting the coating film to a heat treatment to permit hardening.

A CVD procedure used for formation of the metal-containing layer (T) is exemplified by plasma-enhanced CVD, low-pressure CVD, epitaxial growth, and the like. The PVD procedure is exemplified by a sputtering procedure, an evaporation procedure, and the like. The metal-containing layer (T) to be formed by the CVD procedure, the PVD procedure, or the like is exemplified by a titanium oxide film, a titanium nitride film, a zirconium oxide film, an aluminum oxide film, an aluminum oxynitride film, a hafnium oxide film, and the like.

Examples of the metal-containing substrate as the substrate (P) include: Ti-containing substrates such as a titanium-containing substrate, a titanium oxide-containing substrate, and a titanium nitride-containing substrate; Zr-containing substrates such as a zirconium oxide-containing substrate and a zirconium nitride-containing substrate; Hf-containing substrates such as a hafnium oxide-containing substrate; Zn-containing substrates such as a zinc oxide-containing substrate; Al-containing substrates such as an aluminum oxide-containing substrate and an aluminum oxynitride-containing substrate; and the like.

Surface Treatment Agent-Applying Step

In this step, the surface treatment agent (S) is applied on a surface of the substrate (P), the surface containing the metal element (a) (hereinafter, may be also referred to as “surface (Q)”). Hereinafter, the surface treatment agent (S) will be described.

Surface Treatment Agent

The surface treatment agent (S) contains a polymer (C) and a solvent (D). The surface treatment agent (S) may contain, besides the polymer (C) and the solvent (D), other component(s).

Polymer (C)

The polymer (C) is a polymer that includes a group having a polar group (hereinafter, may be also referred to as “group (I)”) at at least one end of a main chain. The “main chain” as referred to herein means the longest atomic chain of atomic chains that constitute the polymer.

Group (I)

The group (I) is a group having a polar group. The “polar group” as referred to herein means a group having at least one hetero atom. Examples of the hetero atom include an oxygen atom, a nitrogen atom, a sulfur atom, a silicon atom, a phosphorus atom, a titanium atom, a tin atom, a boron atom, a halogen atom, and the like.

Examples of the polar group include a hydroxy group, a carboxy group, a sulfo group, a sulfanyl group, a silanol group, a phosphonate group (—PO(OH)₂), a carboxylic acid ester group (—COOR), an isocyanate group, a titanic acid ester group (—TiO(OR)), a titanol group (—TiOH), an amino group, —SiCl, —SiH, and the like, wherein R represents a monovalent hydrocarbon group having 1 to 20 carbon atoms. Of these, a hydroxy group, a carboxy group, a sulfo group, a sulfanyl group, or a silanol group is preferred, and a hydroxy group is more preferred.

The main chain of the polymer (C) is constituted by a plurality of structural units. The polymer (C) may be either a homopolymer constituted by one type of a structural unit, or a copolymer constituted by a plurality of types of structural units. The polymer (C) constituted by the plurality of types of structural units may be either a block copolymer or a random copolymer.

The structural unit that constitutes the main chain of the polymer (C) is not particularly limited, and examples of a monomer that gives the structural unit include substituted or unsubstituted styrene, substituted or unsubstituted ethylene (excluding the substituted or unsubstituted styrene), and the like.

Examples of the substituted styrene include: α-methylstyrene, o-,m-,p-methylstyrene; p-t-butylstyrene; 2,4,6-trimethylstyrene; p-methoxystyrene; p-t-butoxystyrene; o-,m-,p-vinylstyrene; o-,m-,p-hydroxy styrene; m-,p-chloromethylstyrene; p-chlorostyrene; p-bromostyrene; p-iodostyrene; p-nitrostyrene; p-cyanostyrene; and the like.

Examples of the substituted ethylene include: alkenes such as propene, butene, and pentene; vinylcycloalkanes such as vinylcyclopentane and vinyl cyclohexane; cycloalkenes such as cyclopentene, and cyclohexene; 4-hydroxy-1-butene; vinyl glycidyl ether; vinyl trimethylsilyl ether; and the like.

The polymer (C) preferably has an aromatic carbocyclic ring. Due to having the aromatic carbocyclic ring, the polymer (C) may be bulkier, whereby the sensitivity as well as the resolution and the collapse-inhibiting property of the resist pattern may be further improved. The aromatic carbocyclic ring in the polymer (C) is exemplified by a benzene ring, a naphthalene ring, an anthracene ring, and the like.

As the monomer that gives the structural unit of the polymer (C), substituted or unsubstituted styrene is preferred, and unsubstituted styrene is more preferred.

Synthesis Procedure of Polymer (C)

The polymer (C) may be synthesized, for example, by living cationic polymerization, living anionic polymerization, living radical polymerization, coordination polymerization (with a Ziegler-Natta catalyst or a metallocene catalyst), or the like. Of these, the living anionic polymerization is preferred in light of easier introduction of the group (I) to the end of the main chain. For example, the polymer (C) may be synthesized by: polymerizing a monomer in presence of a polymerization initiator; treating a polymerization end thereof with a chain-end terminator; and introducing the group (I) to the end of the main chain.

Examples of a solvent used for polymerization include: alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethyl benzene, and cumene; saturated carboxylic acid esters such as ethyl acetate, n-butyl acetate, i-butyl acetate, and methyl propionate; ketones such as acetone, 2-butanone, 4-methyl-2-pentanone, 2-heptanone, and cyclohexanone; ethers such as tetrahydrofuran, dimethoxyethanes, and diethoxyethanes; and the like. These solvents may be used either alone, or in a combination of two or more types thereof.

A reaction temperature in polymerization may be appropriately selected in accordance with the type of an anionic polymerization initiator, or the like, and the lower limit of the reaction temperature is preferably −150° C., and more preferably −80° C. The upper limit of the reaction temperature is preferably 50° C., and more preferably 40° C. The lower limit of a time period of the reaction is preferably 5 min, and more preferably 20 min. The upper limit of the time period is preferably 24 hrs, and more preferably 12 hrs.

Examples of the anionic polymerization initiator used for the living anionic polymerization include alkyl lithium; alkyl magnesium halide; naphthalene sodium; alkylated lanthanoid compounds; potassium alkoxides such as t-butoxy potassium and 18-crown-6-ether potassium; alkyl zinc such as dimethyl zinc and diethyl zinc; alkyl aluminum such as trimethyl aluminum; aromatic metal compounds such as benzyl potassium, cumyl potassium, cumyl cesium, and the like; and the like. Of these, alkyl lithium is preferred.

Examples of the chain-end terminator that gives the group (I) include: epoxy compounds such as 1,2-butylene oxide, butyl glycidyl ether, propylene oxide, ethylene oxide, 2-ethylhexyl glycidyl ether, and epoxy amine; nitrogen-containing compounds such as an isocyanate compound, a thioisocyanate compound, imidazolidinone, imidazole, aminoketone, pyrrolidone, diethylaminobenzophenone, a nitrile compound, aziridine, formamide, epoxyamine, benzylamine, an oxime compound, azine, hydrazone, imine, an azocarboxylic acid ester, aminostyrene, vinylpyridine, aminoacrylate, aminodiphenylethylene, and an imide compound; silane compounds such as alkoxysilane, aminosilane, ketoiminosilane, isocyanate silane, siloxane, glycidyl silane, mercaptosilane, vinylsilane, epoxysilane, pyridylsilane, piperidylsilane, pyrrolidonesilane, cyanosilane, and silane isocyanate; halogenated tin; halogenated silicon; carbon dioxide; and the like. Further, when a halogenated dioxolane compound such as 4-chloromethyl-2,2-dimethyl-1,3-dioxolane is used as the chain-end terminator, the group (I) having a diol structure can be formed through a hydrolysis reaction. As the chain-end terminator, the epoxy compound or a halogenated oxolane compound is preferred, and 2-ethylhexyl glycidyl ether, ethylene oxide, or 4-chloromethyl-2,2-dimethyl-1,3-dioxolane is more preferred.

The polymer (C) formed by polymerization is preferably collected by a reprecipitation technique. More specifically, after completion of the reaction, a reaction liquid is charged into a reprecipitation solvent to collect an intended polymer in the form of powder. As the reprecipitation solvent, an alcohol, ultrapure water, an alkane, or the like may be used either alone, or as a mixture of two or more types thereof. As an alternative to the reprecipitation technique, the polymer may be collected by eliminating low molecular weight components such as monomers and oligomers through a liquid separation operation, a column operation, an ultrafiltration operation, or the like.

The lower limit of a polystyrene-equivalent weight average molecular weight (Mw) of the polymer (C) as determined by gel permeation chromatography (GPC) is preferably 2,000, more preferably 3,000, still more preferably 4,000, and particularly preferably 5,000. The upper limit of the Mw is preferably 500,000, more preferably 100,000, still more preferably 10,000, and particularly preferably 7,000.

The lower limit of a polystyrene-equivalent number average molecular weight (Mn) of the polymer (C) is preferably 2,000, more preferably 3,000, still more preferably 4,000, and particularly preferably 5,000. The upper limit of the Mn is preferably 500,000, more preferably 100,000, still more preferably 10,000, and particularly preferably 7,000.

The upper limit of a dispersity index (Mw/Mn) of the polymer (C) is preferably 5, more preferably 3, still more preferably 2, particularly preferably 1.5, more particularly preferably 1.2, and most preferably 1.1. The lower limit of the dispersity index is typically 1.

Herein, the Mw and the Mn of the polymer (C) are values determined by GPC using GPC columns (“G2000HXL”×2; “G3000HXL”×1; and “G4000HXL”×1, available from Tosoh Corporation) under an analytical condition involving a flow rate of 1.0 mL/min, an elution solvent of tetrahydrofuran, a sample concentration of 1.0% by mass, an amount of injected sample of 100 μL, and a column temperature of 40° C., with mono-dispersed polystyrene as a standard, wherein a differential refractometer is used as a detector.

The lower limit of a percentage content of the polymer (C) in the surface treatment agent (S) with respect to all components other than the solvent (D) is preferably 70% by mass, more preferably 80% by mass, and still more preferably 90% by mass. The upper limit of the percentage content may be 100% by mass. When the percentage content of the polymer (C) falls within the above range, coating characteristics of the surface treatment agent (S) can be further improved. The surface treatment agent (S) may contain one, or two or more types of the polymer (C).

Solvent (D)

The solvent (D) is not particularly limited as long as it is capable of dissolving or dispersing the polymer (C) and other component(s) which may be contained as needed. The solvent (D) is exemplified by alcohol solvents, ketone solvents, ether solvents, ester solvents, nitrogen-containing solvents, water, and the like. The solvent (D) may be used either alone of one type, or in a combination of two or more types thereof. Examples of the solvent (D) include the solvents and the like exemplified as the solvent (B) of the metal-containing composition (X).

As the solvent (D), an ester solvent is preferred, a polyvalent alcohol partial ether carboxylate solvent is more preferred, and propylene glycol monomethyl ether acetate is still more preferred.

Other Component(s)

Examples of the other component(s) in the surface treatment agent (S) include a surfactant and the like. In a case in which the surface treatment agent (S) includes the other component(s), the upper limit of a content of the other component(s) is preferably 5 parts by mass with respect to 100 parts by mass of the polymer (C), and more preferably 1 part by mass.

Preparation Procedure of Surface Treatment Agent

A preparation procedure of the surface treatment agent (S) is not particularly limited, and it may be prepared by, for example, mixing at a predetermined ratio the compound (C), the solvent (D), and the other component(s) which may be contained as needed, and preferably filtering a thus resulting mixed solution through a filter having a pore size of no greater than 0.2 μm.

The lower limit of a solid content concentration of the surface treatment agent (S) is preferably 0.01% by mass, more preferably 0.1% by mass, still more preferably 0.5% by mass, and particularly preferably 1% by mass. The upper limit of the solid content concentration is preferably 20% by mass, more preferably 10% by mass, still more preferably 5% by mass, and particularly preferably 3% by mass. The “solid content concentration” of the surface treatment agent (S) as referred to herein means a value (% by mass) as determined by: baking the surface treatment agent (S) at 250° C. for 30 min; measuring a mass of the solid content in the surface treatment agent (S); and dividing the mass of the solid content by the mass of the surface treatment agent (S).

A procedure for applying the surface treatment agent (S) on the surface (Q) is exemplified by spin coating, roll coating, dip coating, and the like. This allows a coating film of the surface treatment agent (S) to be formed on the surface (Q) of the substrate (P).

In the surface treatment agent-applying step, the coating film of the surface treatment agent (S) may be subjected to heating. The lower limit of a temperature of the heating is preferably 80° C., and more preferably 100° C. The upper limit of the temperature is preferably 250° C., and more preferably 200° C. The lower limit of a time period of the heating is preferably 10 sec, and more preferably 30 sec. The upper limit of the time period is preferably 30 min, and more preferably 10 min.

In the surface treatment agent-applying step, the coating film of the surface treatment agent (S) may be washed with a solvent before or after the heating. Examples of the solvent used for washing include the solvents and the like exemplified as the solvent (B) of the metal-containing composition (X). Of these, the ester solvent is preferred, a polyvalent alcohol partial ether carboxylate solvent is more preferred, and propylene glycol monomethyl ether acetate is still more preferred. As a washing procedure, for example, an applying procedure such as spin coating, roll coating, dip coating, or the like may be employed.

The lower limit of an average thickness of a film (the coating film) which is formed from the surface treatment agent (S), on the surface (Q) is preferably 0.1 nm, more preferably 0.5 nm, and still more preferably 1 nm. The upper limit of the average thickness is preferably 10 nm, more preferably 5 nm, and still more preferably 3 nm. When the average thickness of the film which is formed from the surface treatment agent (S), on the surface (Q) falls within the above range, the sensitivity as well as the resolution and the collapse-inhibiting property of the resist pattern can be further improved.

Treatment Step

The substrate-producing method may further include a treatment step before the resist composition-applying step. In the treatment step, the face (the surface) of the substrate (P) on which the surface treatment agent has been applied is treated with one, or two or more of: exposure to an ultraviolet ray, exposure to oxygen plasma, contact with water, contact with an alkali, contact with an acid, contact with hydrogen peroxide, and contact with ozone.

In this step, only one treatment from among the exposure to an ultraviolet ray, exposure to oxygen plasma, contact with water, contact with an alkali, contact with an acid, contact with hydrogen peroxide, and contact with ozone may be carried out; or two or more treatments thereof may be carried out either sequentially or simultaneously.

The lower limit of the wavelength of the ultraviolet ray is preferably 13 nm, and more preferably 150 nm. The upper limit of the wavelength is preferably 370 nm, and more preferably 255 nm.

Resist Composition-Applying Step

In this step, a resist composition is applied on the face on which the surface treatment agent has been applied. Hereinafter, the resist composition will be described.

Resist Composition

The resist composition is exemplified by a radiation-sensitive resin composition containing a polymer having an acid-labile group and a radiation-sensitive acid generating agent (a chemically amplified resist composition), a positive tone resist composition containing an alkali-soluble resin and a quinone diazide-based photosensitizing agent, a negative tone resist composition containing an alkali-soluble resin and a crosslinking agent, a radiation-sensitive composition containing a metal-containing compound (a metal resist composition), and the like. Of these, the radiation-sensitive resin composition is preferred. In a case in which the radiation-sensitive resin composition is used, formation of a positive tone pattern is enabled by developing with an alkaline developer solution, whereas formation of a negative tone pattern is enabled by developing with an organic solvent developer solution.

The polymer contained in the radiation-sensitive resin composition may have, in addition to a structural unit that includes the acid-labile group, for example, a structural unit that includes a lactone structure, a cyclic carbonate structure, and/or a sultone structure; a structural unit that includes an alcoholic hydroxyl group; a structural unit that includes a phenolic hydroxyl group; a structural unit that includes a fluorine atom, etc.

A procedure for applying the resist composition on the face on which the surface treatment agent (S) has been applied may be exemplified by conventional procedures such as spin coating and the like.

By prebaking a coating film of the resist composition, the resist film is formed by allowing the solvent in the coating film to be volatilized.

Exposing Step

In this step, the resist film formed by the applying step is exposed to the extreme ultraviolet ray or the electron beam. The exposure may be carried out by using a reflective mask and selectively irradiating with a radioactive ray, for example.

Developing Step

In this step, the resist film exposed is developed. This allows the resist pattern to be formed.

The developing may be a development with an alkali or a development with an organic solvent. According to the substrate-producing method, the sensitivity of the resist film to the extreme ultraviolet ray or the electron beam in the exposing can be increased, and a resist pattern superior in resolution and the collapse-inhibiting property can be formed. In particular, it is considered that generation of a residue of the resist film is inhibited for a positive tone resist pattern obtained by the development with the alkali, leading to superior resolution; a negative tone resist pattern obtained by the development with the organic solvent is considered to appropriately maintain adhesiveness with a face that the resist film in contact with, leading to a collapse-inhibiting property being superior. In this way, according to the substrate-producing method, formation of a favorable resist pattern is enabled.

Examples of the alkaline developer solution include alkaline aqueous solutions of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, and 1,5-diazabicyclo[4.3.0]-5-nonene; and the like. Further, appropriate amounts of water-soluble organic solvents such as alcohols such as methanol and ethanol; surfactants; and the like may be added to these alkaline aqueous solutions.

The organic solvent developer solution is exemplified by liquids in which a principle component is an organic solvent such as a ketone solvent, an alcohol solvent, an amide solvent, an ether solvent, or an ester solvent; and the like. Examples of these solvents include solvents similar to those exemplified as the solvent (B) of the metal-containing composition (X), and more specific examples include n-butyl acetate, iso-butyl acetate, sec-butyl acetate, amyl acetate, and the like. These solvents may be used either alone of one type, or as a mixture of multiple types thereof.

After the developing has been conducted with a developer solution (the alkaline developer solution or the organic solvent developer solution), a resist pattern can be obtained by preferably washing and then drying.

Etching Step

In this step, by using as a mask the resist pattern formed by the developing step, the substrate is etched. More specifically, a patterned substrate is obtained by etching once or a plurality of times, with the resist pattern as a mask.

In a case in which the substrate (P) has an organic underlayer film and the metal-containing layer (T) formed on the base, a pattern is formed on the base by: etching the metal-containing layer (T) with the resist pattern as a mask to form a metal-containing layer pattern; etching the organic underlayer film with the metal-containing layer pattern as a mask to form an organic underlayer film pattern; and etching the base with the organic underlayer film pattern as a mask.

The etching may be either dry etching or wet etching, and dry etching is preferred.

The dry etching may be carried out by using, for example, a known dry etching apparatus. An etching gas used for the dry etching may be appropriately selected depending on element composition and the like of the metal-containing layer (T) and the organic underlayer film to be etched. Examples of the etching gas which may be used include: fluorine-based gases such as CHF₃, CF₄, C₂F₆, C₃F₈ and SF₆; chlorine-based gases such as Cl₂ and BCl₃; oxygen-based gases such as O₂, O₃, and H₂O; reductive gases such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃; inert gases such as He, N₂ and Ar; and the like. These gases may be used as a mixture. In dry etching of the metal-containing layer (T), the fluorine-base gas is typically used, and a mixture obtained by adding an oxygen-based gas and an inert gas to the fluorine-based gas may be suitably used. Further, in dry etching of the organic underlayer film, the oxygen-based gas is typically used.

### EXAMPLES

Examples of the present invention will be demonstrated below. It is to be noted that the following Examples merely illustrate one typical example of the present invention, and the scope of the present invention should not be construed to be narrowed by the Examples.

### Preparation of Metal-Containing Composition

In the present Examples, measurements of: the solid content concentration of a solution of the compound (A); the weight average molecular weight (Mw) of the compound (A); and the average thickness of the film were conducted according to the following procedures.

Solid Content Concentration of Solution of Compound (A)

A solid content concentration (% by mass) of the solution of the compound (A) was calculated by baking 0.5 g of the solution of the compound (A) at 250° C. for 30 min to measure a mass of a solid content in 0.5 g of the solution.

Weight Average Molecular Weight (Mw)

Measurements were carried out by gel permeation chromatography (detector: differential refractometer) by using GPC columns (“AWM-H”×2, “AW-H”×1, and “AW2500”×2, available from Tosoh Corporation) under an analytical condition involving: a flow rate of 0.3 mL/min; an elution solvent of a mixture prepared by adding LiBr (30 mM) and citric acid (30 mM) to N,N-dimethylacetamide; and a column temperature of 40° C., with mono-dispersed polystyrene as a standard.

Average Thickness of Film

The average thickness of the film was measured by using a spectroscopic ellipsometer (“M2000D,” available from J.A. Woollam Co.).

Synthesis of Compound (A)

Metal-containing compounds used for the syntheses of the compounds (A) are as presented below. It is to be noted that in the following Synthesis Examples, “parts by mass” means a value, provided that a total mass of the metal-containing compound used was 100 parts by mass, unless otherwise specified particularly.

M-1: diisopropoxybis(2,4-pentanedionato) titanium(IV) (a solution in 2-propanol with a concentration of 75% by mass)

M-2: dibutoxybis(ethylacetoacetate) zirconium(IV) (a solution in n-butanol with a concentration of 70% by mass)

M-3: tetramethoxysilane

M-4: methyltrimethoxysilane

M-5: diisopropoxyethylacetoacetate aluminum(III) (a solution in 2-propanol with a concentration of 75% by mass)

### Synthesis Example 1-1

### Synthesis of Compound (A-1)

In a reaction vessel, the compound (M-1) (100 parts by mass, excluding the solvent) was dissolved in 468 parts by mass of propylene glycol monoethyl ether. In the reaction vessel, 53 parts by mass of water were added dropwise over 10 min with stirring at room temperature (25° C. to 30° C.). Subsequently, the reaction was allowed at 60° C. for 2 hrs. After completion of the reaction, the interior of the reaction vessel was cooled to no greater than 30° C. To the reaction solution thus cooled were added 654 parts by mass of propylene glycol monoethyl ether. Thereafter, water, alcohol generated by the reaction, and excess propylene glycol monoethyl ether were removed by using an evaporator to give a solution of a compound represented by the following formula (A-1) (hereinafter, may be also referred to as “compound (A-1)”) in propylene glycol monoethyl ether. The Mw of the compound (A-1) was 4,200. The solid content concentration of the propylene glycol monoethyl ether solution of the compound (A-1) was 7.6% by mass.

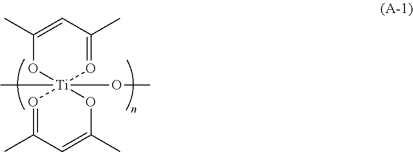

### Synthesis Example 1-2

### Synthesis of Compound (A-2)

In a reaction vessel, the compound (M-2) (100 parts by mass, excluding the solvent) was dissolved in 1,325 parts by mass of propylene glycol monoethyl ether. In the reaction vessel, 7 parts by mass of water were added dropwise over 10 min with stirring at room temperature (25° C. to 30° C.). Subsequently, the reaction was allowed at 60° C. for 2 hrs. After completion of the reaction, the interior of the reaction vessel was cooled to no greater than 30° C. To the reaction solution thus cooled were added 981 parts by mass of propylene glycol monoethyl ether. Thereafter, water, alcohol generated by the reaction, and excess propylene glycol monoethyl ether were removed by using an evaporator to give a solution of a compound represented by the following formula (A-2) (hereinafter, may be also referred to as “compound (A-2)”) in propylene glycol monoethyl ether. The Mw of the compound (A-2) was 2,400. The solid content concentration of the propylene glycol monoethyl ether solution of the compound (A-2) was 13.0% by mass.

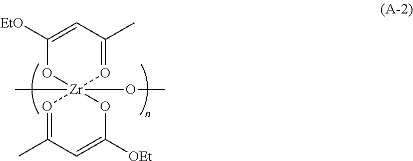

### Synthesis Example 1-3

### Synthesis of Compound (A-3)

In a reaction vessel, the compound (M-1) (50 mol %) and the compound (M-3) (50 mol %) were dissolved in 343 parts by mass of isopropyl alcohol. In the reaction vessel, a mixture of 22.3 parts by mass of a 6.2% by mass aqueous oxalic acid solution and 343 parts by mass of isopropyl alcohol was added dropwise over 20 min with stirring at 40° C. Subsequently, the reaction was allowed at 60° C. for 2 hrs. After completion of the reaction, the interior of the reaction vessel was cooled to no greater than 30° C. To the reaction solution thus cooled were added 809 parts by mass of propylene glycol monoethyl ether. Thereafter, water, alcohol generated by the reaction, and excess propylene glycol monoethyl ether were removed by using an evaporator to give a solution of a compound represented by the following formula (A-3) (hereinafter, may be also referred to as “compound (A-3)”) in propylene glycol monoethyl ether. The Mw of the compound (A-3) was 14,000. The solid content concentration of the propylene glycol monoethyl ether solution of the compound (A-3) was 4.0% by mass.

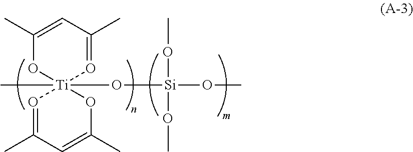

### Synthesis Example 1-4

### Synthesis of Compound (A-4)

In a reaction vessel, the compound (M-1) (50 mol %), the compound (M-3) (20 mol %), and the compound (M-4) (30 mol %) were dissolved in 364 parts by mass of isopropyl alcohol. In the reaction vessel, a mixture of 24.3 parts by mass of a 5.9% by mass aqueous oxalic acid solution and 364 parts by mass of isopropyl alcohol was added dropwise over 20 min with stirring at 40° C. Subsequently, the reaction was allowed at 60° C. for 2 hrs. After completion of the reaction, the interior of the reaction vessel was cooled to no greater than 30° C. To the reaction solution thus cooled were added 849 parts by mass of propylene glycol monoethyl ether. Thereafter, water, alcohol generated by the reaction, and excess propylene glycol monoethyl ether were removed by using an evaporator to give a solution of a compound represented by the following formula (A-4) (hereinafter, may be also referred to as “compound (A-4)”) in propylene glycol monoethyl ether. The Mw of the compound (A-4) was 8,500. The solid content concentration of the propylene glycol monoethyl ether solution of the compound (A-4) was 4.0% by mass.

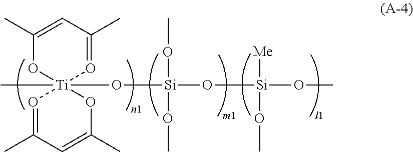

### Synthesis Example 1-5

### Synthesis of Compound (A-5)

In a reaction vessel, the compound (M-5) (10 mol %) and the compound (M-4) (90 mol %) were dissolved in 198 parts by mass of propylene glycol monoethyl ether. In the reaction vessel, 39 parts by mass of a 17.6% by mass aqueous acetic acid solution were added dropwise over 10 min with stirring at room temperature (25° C. to 30° C.). Subsequently, the reaction was allowed at 95° C. for 5 hrs. After completion of the reaction, the interior of the reaction vessel was cooled to no greater than 30° C. To the reaction solution thus cooled were added 471 parts by mass of propylene glycol monoethyl ether. Thereafter, water, alcohol generated by the reaction, and excess propylene glycol monoethyl ether were removed by using an evaporator to give a solution of a compound represented by the following formula (A-5) (hereinafter, may be also referred to as “compound (A-5)”) in propylene glycol monoethyl ether. The Mw of the compound (A-5) was 2,700. The solid content concentration of the propylene glycol monoethyl ether solution of the compound (A-5) was 13.1% by mass.

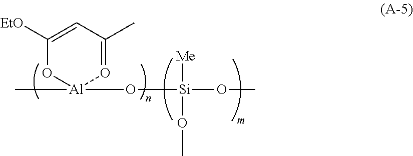

### Synthesis Example 1-6

### Synthesis of Compound (A-6)

In a reaction vessel, the compound (M-1) (45 mol %), the compound (M-3) (30 mol %), and the compound (M-4) (25 mol %) were dissolved in 373 parts by mass of isopropyl alcohol. In the reaction vessel, a mixture of 21.5 parts by mass of a 1.7% by mass aqueous oxalic acid solution and 373 parts by mass of isopropyl alcohol was added dropwise over 20 min with stirring at 40° C. Subsequently, the reaction was allowed at 60° C. for 2 hrs. After completion of the reaction, the interior of the reaction vessel was cooled to no greater than 30° C. To the reaction solution thus cooled were added 867 parts by mass of propylene glycol monoethyl ether acetate. Thereafter, water, alcohol generated by the reaction, and excess propylene glycol monoethyl ether acetate were removed by using an evaporator to give a solution of a compound represented by the following formula (A-6) (hereinafter, may be also referred to as “compound (A-6)”) in propylene glycol monoethyl ether acetate. The Mw of the compound (A-6) was 1,400. The solid content concentration of the propylene glycol monoethyl ether acetate solution of the compound (A-6) was 5.6% by mass.

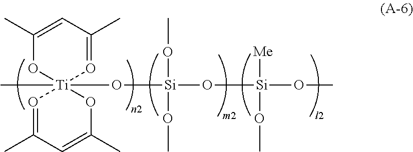

### Synthesis Example 1-7

### Synthesis of Compound (A-7)

In a reaction vessel, the compound (M-1) (40 mol %), the compound (M-3) (30 mol %), and the compound (M-4) (30 mol %) were dissolved in 370 parts by mass of isopropyl alcohol. In the reaction vessel, a mixture of 23.0 parts by mass of a 1.8% by mass aqueous oxalic acid solution and 370 parts by mass of isopropyl alcohol was added dropwise over 20 min with stirring at 40° C. Subsequently, the reaction was allowed at 60° C. for 2 hrs. After completion of the reaction, the interior of the reaction vessel was cooled to no greater than 30° C. To the reaction solution thus cooled were added 900 parts by mass of propylene glycol monoethyl ether acetate. Thereafter, water, alcohol generated by the reaction, and excess propylene glycol monoethyl ether acetate were removed by using an evaporator to give a solution of a compound represented by the following formula (A-7) (hereinafter, may be also referred to as “compound (A-7)”) in propylene glycol monoethyl ether acetate. The Mw of the compound (A-7) was 1,500. The solid content concentration of the propylene glycol monoethyl ether acetate solution of the compound (A-7) was 5.4% by mass.

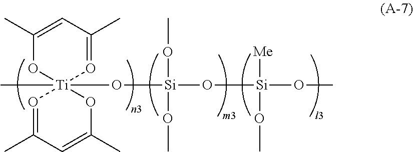

### Synthesis Example 1-8

### Synthesis of Compound (A-8)

In a reaction vessel, the compound (M-1) (30 mol %), the compound (M-3) (30 mol %), and the compound (M-4) (40 mol %) were dissolved in 430 parts by mass of isopropyl alcohol. In the reaction vessel, a mixture of 26.4 parts by mass of a 2.0% by mass aqueous oxalic acid solution and 430 parts by mass of isopropyl alcohol was added dropwise over 20 min with stirring at 40° C. Subsequently, the reaction was allowed at 60° C. for 2 hrs. After completion of the reaction, the interior of the reaction vessel was cooled to no greater than 30° C. To the reaction solution thus cooled were added 849 parts by mass of propylene glycol monoethyl ether acetate. Thereafter, water, alcohol generated by the reaction, and excess propylene glycol monoethyl ether acetate were removed by using an evaporator to give a solution of a compound represented by the following formula (A-8) (hereinafter, may be also referred to as “compound (A-8)”) in propylene glycol monoethyl ether acetate. The Mw of the compound (A-8) was 1,700. The solid content concentration of the propylene glycol monoethyl ether acetate solution of the compound (A-8) was 5.5% by mass.

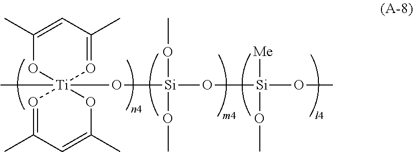

### Synthesis Example 1-9

### Synthesis of Compound (A-9)

In a reaction vessel, the compound (M-1) (20 mol %) and the compound (M-4) (80 mol %) were dissolved in 510 parts by mass of isopropyl alcohol. In the reaction vessel, a mixture of 28.4 parts by mass of a 2.1% by mass aqueous oxalic acid solution and 510 parts by mass of isopropyl alcohol was added dropwise over 20 min with stirring at 40° C. Subsequently, the reaction was allowed at 60° C. for 2 hrs. After completion of the reaction, the interior of the reaction vessel was cooled to no greater than 30° C. To the reaction solution thus cooled were added 1,150 parts by mass of propylene glycol monoethyl ether acetate. Thereafter, water, alcohol generated by the reaction, and excess propylene glycol monoethyl ether acetate were removed by using an evaporator to give a solution of a compound represented by the following formula (A-9) (hereinafter, may be also referred to as “compound (A-9)”) in propylene glycol monoethyl ether acetate. The Mw of the compound (A-9) was 2,000. The solid content concentration of the propylene glycol monoethyl ether acetate solution of the compound (A-9) was 5.6% by mass.

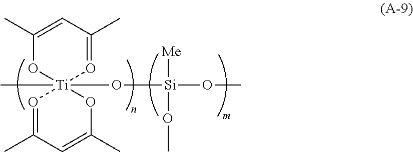

Preparation of Metal-Containing Composition

Solvents (B) used in the preparation of the metal-containing compositions are as presented below.

Solvent (B)

B-1: propylene glycol monoethyl ether

B-2: propylene glycol monomethyl ether acetate

### Preparation Example 1-1

A metal-containing composition (X-1) was prepared by mixing: as the compound (A) (solid content), 2 parts by mass of (A-1); and as the solvent (B), 95 parts by mass of (B-1) (including the solvent (B-1) contained in the solution of the compound (A)) and 5 parts by mass of (B-2), and filtering a thus resulting solution through a filter having a pore size of 0.2 μm.

### Preparation Examples 1-2 to 1-11

Metal-containing compositions (X-2) to (X-11) were prepared by a similar operation to Preparation Example 1-1 except that the type and the content of each component were as shown in Table 1 below.

TABLE 1

| | | (A) Compound | | (B) Solvent | |
|---|---|---|---|---|---|
| | Metal- | | content | | content |
| | containing | | (parts | | (parts |
| | composition | type | by mass) | type | by mass) |
| Preparation | X-1 | A-1 | 2 | B-1/B-2 | 95/5 |
| Example 1-1 | | | | | |
| Preparation | X-2 | A-2 | 2 | B-1/B-2 | 95/5 |
| Example 1-2 | | | | | |
| Preparation | X-3 | A-3 | 2 | B-1/B-2 | 95/5 |
| Example 1-3 | | | | | |
| Preparation | X-4 | A-4 | 2 | B-1/B-2 | 95/5 |
| Example 1-4 | | | | | |
| Preparation | X-5 | A-5 | 2 | B-1/B-2 | 95/5 |
| Example 1-5 | | | | | |
| Preparation | X-6 | A-6 | 2 | B-1/B-2 | 50/50 |
| Example 1-6 | | | | | |
| Preparation | X-7 | A-7 | 2 | B-1/B-2 | 50/50 |
| Example 1-7 | | | | | |
| Preparation | X-8 | A-6 | 2 | B-2 | 100 |
| Example 1-8 | | | | | |
| Preparation | X-9 | A-7 | 2 | B-2 | 100 |
| Example 1-9 | | | | | |
| Preparation | X-10 | A-8 | 2 | B-2 | 100 |
| Example 1-10 | | | | | |
| Preparation | X-11 | A-9 | 2 | B-2 | 100 |
| Example 1-11 | | | | | |

### Production of Substrate

Production of Substrate (JF-1-1)

A substrate (JF-1-1) was obtained by applying on a silicon base the metal-containing composition (X-1) prepared as above, by spin coating with a spin coater (“CLEAN TRACK ACT8,” available from Tokyo Electron Limited) and heating at 220° C. for 60 sec, followed by cooling at 23° C. for 30 sec to form a metal-containing layer having an average thickness of 30 nm.

Production of Substrate (JF-1-2)

A substrate (JF-1-2) was obtained by applying on a silicon base the metal-containing composition (X-2) prepared as above, by spin coating with the spin coater and heating at 220° C. for 60 sec, followed by cooling at 23° C. for 30 sec to form a metal-containing layer having an average thickness of 30 nm.

Production of Substrate (JF-1-3)

A substrate (JF-1-3) was obtained by applying on a silicon base the metal-containing composition (X-3) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-4)

A substrate (JF-1-4) was obtained by applying on a silicon base the metal-containing composition (X-4) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-5)

A substrate (JF-1-5) was obtained by applying on a silicon base the metal-containing composition (X-5) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-6)

A substrate (JF-1-6) was obtained by applying on a silicon base the metal-containing composition (X-6) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-7)

A substrate (JF-1-7) was obtained by applying on a silicon base the metal-containing composition (X-7) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-8)

A substrate (JF-1-8) was obtained by applying on a silicon base the metal-containing composition (X-8) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-9)

A substrate (JF-1-9) was obtained by applying on a silicon base the metal-containing composition (X-9) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-10)

A substrate (JF-1-10) was obtained by applying on a silicon base the metal-containing composition (X-10) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-1-11)

A substrate (JF-1-11) was obtained by applying on a silicon base the metal-containing composition (X-11) prepared as above, by spin coating with the spin coater and heating at 220° C. for 60 sec, followed by cooling at 20° C. to 25° C. for 30 sec to form a metal-containing layer having an average thickness of 30 nm.

Production of Substrate (JF-2-1)

A substrate (JF-2-1) provided thereon with a methacrylic-based resin film having an average thickness of 60 nm was obtained by applying “DUV42,” a methacrylic-based resin composition available from Brewer Science, Inc., on the substrate (JF-1-1) formed as above, by spin coating with the spin coater and heating at 205° C. for 60 sec, followed by cooling at 20° C. to 25° C. for 30 sec.

Production of Substrates (JF-2-2) to (JF-2-5)

In a manner similar to that of the substrate (JF-2-1) formed as above, substrates (JF-2-2) to (JF-2-5) each provided thereon with a methacrylic-based resin film having an average thickness of 60 nm were obtained by applying the “DUV42” on the substrates (JF-1-2) to (JF-1-5) formed as above, by spin coating with the spin coater and heating at 205° C. for 60 sec, followed by cooling at 20° C. to 25° C. for 30 sec.

Production of Substrate (JF-2-6)

A substrate (JF-2-6) provided thereon with a methacrylic-based resin film having an average thickness of 60 nm was obtained by applying the “DUV42” on a silicon base by spin coating with a spin coater and heating at 205° C. for 60 sec, followed by cooling at 20° C. to 25° C. for 30 sec.

### Preparation of Surface Treatment Agent

In the present Examples, the weight average molecular weight (Mw) and the number average molecular weight (Mn) of the polymer (C) were measured by the following procedures.

Mw and Mn

The Mw and the Mn of the polymer (C) were measured by gel permeation chromatography (GPC) using GPC columns (“G2000HXL”×2; “G3000HXL”×1; and “G4000HXL”×1, available from Tosoh Corporation) under the following conditions:

eluent: tetrahydrofuran (Wako Pure Chemical Industries, Ltd.);

flow rate: 1.0 mL/min;

sample concentration: 1.0% by mass;

amount of injected sample: 100 μL;

column temperature: 40° C.;

detector: differential refractometer; and

standard substance: mono-dispersed polystyrene.

Synthesis of Polymer (C)

### Synthesis Example 2-1

### Synthesis of Polymer (C-1)

A reaction flask was dried under reduced pressure, and then 120 g of tetrahydrofuran (THF), which had been subjected to a dehydrating treatment by distillation, was charged thereinto in a nitrogen atmosphere, and then cooled to −78° C. Thereafter, 3.10 mL of a 1 N cyclohexane solution of sec-butyllithium (sec-BuLi) was charged into this THF, and then 16.6 mL of styrene, which had been subjected to adsorptive filtration through silica gel for removing a polymerization inhibitor and to a dehydrating treatment by distillation, was charged by dropwise addition thereinto over 30 min, and the color of a polymerization system was ascertained to be orange. During the charging by dropwise addition, the internal temperature of the polymerization reaction mixture was carefully controlled so as not to be −60° C. or greater. After completion of the dropwise addition, aging was permitted for 30 min. Subsequently, a mixture of 0.63 mL of 2-ethylhexyl glycidyl ether and 1 mL of methanol was charged as a chain-end terminator to conduct a terminating reaction of the polymerization end. The temperature of the polymerization reaction mixture was elevated to room temperature and the polymerization reaction mixture was concentrated, and then the solvent was replaced with methyl isobutyl ketone (MIBK). Thereafter, 1,000 g of a 2% by mass aqueous oxalic acid solution was charged, a resultant mixture was stirred and left to stand still, and then an aqueous underlayer was removed. This operation was repeated three times to remove a Li salt. Thereafter, 1,000 g of ultrapure water was charged, a resultant mixture was stirred and left to stand still, and then an aqueous underlayer was removed. After this operation was repeated three times to remove oxalic acid, a solution thus obtained was concentrated and then dropped into 500 g of methanol to precipitate a polymer, and a solid was collected on a Büchner funnel. The polymer thus obtained was dried under reduced pressure at 60° C., whereby 14.8 g of a white solid of a polymer represented by the following formula (C-1) was obtained. The polymer (C-1) had an Mw of 6,100, an Mn of 5,700, and an Mw/Mn of 1.07.

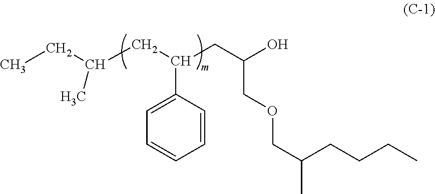

### Synthesis Example 2-2

### Synthesis of Polymer (C-2)

A reaction vessel was dried under reduced pressure, and then 120 g of THF, which had been subjected to a dehydrating treatment by distillation, was charged thereinto in a nitrogen atmosphere and then cooled to −78° C. Thereafter, 2.38 mL of a 1 N cyclohexane solution of sec-BuLi was charged into this THF, and then 13.3 mL of styrene, which had been subjected to adsorptive filtration through silica gel for removing a polymerization inhibitor and to a dehydrating treatment by distillation, was charged by dropwise addition thereinto over 30 min, and the color of a polymerization system was ascertained to be orange. During the charging by dropwise addition, the internal temperature of the reaction mixture was carefully controlled so as not to be −60° C. or greater. After completion of the dropwise addition, aging was permitted for 30 min. Subsequently, 2.40 mL of a THF solution of ethylene oxide having a concentration of 1 mol/L was charged as a chain-end terminator to conduct a terminating reaction of the polymerization end. The temperature of the reaction solution was elevated to room temperature and the reaction solution thus obtained was concentrated, and the solvent was replaced with MIBK. Thereafter, 1,000 g of a 2% by mass aqueous oxalic acid solution was charged, a resultant mixture was stirred and left to stand still, and then an aqueous underlayer was removed. This operation was repeated three times to remove a Li salt. Thereafter, 1,000 g of ultrapure water was charged, a resultant mixture was stirred and left to stand still, and then an aqueous underlayer was removed. After this operation was repeated three times to remove oxalic acid, a resultant solution was concentrated and dropped into 500 g of methanol to precipitate a polymer, and a solid was collected on a Büchner funnel. The polymer was dried under reduced pressure at 60° C., whereby 11.6 g of a white polymer represented by the following formula (C-2) was obtained. The polymer (C-2) had an Mw of 5,300, an Mn of 5,400, and an Mw/Mn of 1.04.

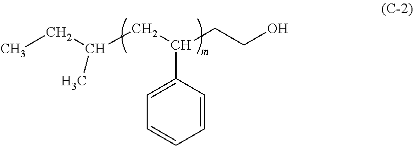

### Synthesis Example 2-3

### Synthesis of Polymer (C-3)

A reaction flask was dried under reduced pressure, and then 120 g of THF, which had been subjected to a dehydrating treatment by distillation, was charged thereinto in a nitrogen atmosphere and then cooled to −78° C. 2.38 mL of a 1 N cyclohexane solution of sec-BuLi was charged into this THF, and further 13.3 mL of styrene, which had been subjected to adsorptive filtration through silica gel for removing a polymerization inhibitor and to a dehydrating treatment by distillation, was charged by dropwise addition thereinto over 30 min, and the color of a polymerization system was ascertained to be orange. During the charging by dropwise addition, the internal temperature of the reaction mixture was carefully controlled so as not to be −60° C. or greater. After completion of the dropwise addition, aging was permitted for 30 min. Next, 0.32 mL of 4-chloromethyl-2,2-dimethyl-1,3-dioxolane was charged as a chain-end terminator to conduct a terminating reaction of the polymerization end. Subsequently, 10 g of a 1 N aqueous hydrochloric acid solution was added thereto, and a hydrolysis reaction was allowed by heating at 60° C. for 2 hrs with stirring, whereby a polymer including a group having a diol structure at an end of a main chain was obtained. The reaction solution was cooled to room temperature and the reaction solution thus obtained was concentrated, and the solvent was replaced with MIBK. Thereafter, 1,000 g of a 2% by mass aqueous oxalic acid solution was charged, a resultant mixture was stirred and left to stand still, and then an aqueous underlayer was removed. This operation was repeated three times to remove a Li salt. Thereafter, 1,000 g of ultrapure water was charged, a resultant mixture was stirred and left to stand still, and then an aqueous underlayer was removed. After this operation was repeated three times to remove oxalic acid, a resultant solution was concentrated and dropped into 500 g of methanol to precipitate a polymer, and a solid was collected on a Büchner funnel. The polymer was dried under reduced pressure at 60° C., whereby 11.3 g of a white polymer represented by the following formula (C-3) was obtained. The polymer (C-3) had an Mw of 5,300, an Mn of 4,900, and an Mw/Mn of 1.08.

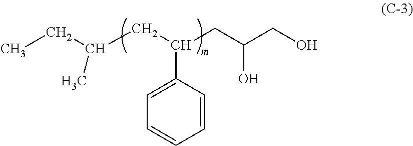

Preparation of Surface Treatment Agent

The solvent (D) used in the preparation of the surface treatment agents is as presented below.

Solvent (D)

D-1: propylene glycol monomethyl ether acetate

### Preparation Example 2-1

A surface treatment agent (S-1) was prepared by mixing: as the polymer (C), 1.2 parts by mass of (C-1); and as the solvent (D), 98.8 parts by mass of (D-1), and filtering a thus resulting solution through a filter having a pore size of 0.2 μm.

### Preparation Example 2-2

A surface treatment agent (S-2) was prepared by mixing: as the polymer (C), 1.2 parts by mass of (C-2); and as the solvent (D), 98.8 parts by mass of (D-1), and filtering a thus resulting solution through a filter having a pore size of 0.2 μm.

### Preparation Example 2-3

A surface treatment agent (S-3) was prepared by mixing: as the polymer (C), 1.2 parts by mass of (C-3); and as the solvent (D), 98.8 parts by mass of (D-1), and filtering a thus resulting solution through a filter having a pore size of 0.2 μm.

### Preparation Example 2-4

A surface treatment agent (S-4) was prepared by mixing: as the polymer (C), 0.1 parts by mass of (C-1); and as the solvent (D), 99.9 parts by mass of (D-1), and filtering a thus resulting solution through a filter having a pore size of 0.2 μm.

### Surface Treatment Agent-Applying Step

The substrates (JF-1-1) to (JF-1-11) produced as above were each subjected to corresponding one of the following treatments (P-1) to (P-3) of the surface treatment agent-applying step as shown in Table 2, using corresponding one of the surface treatment agents (S-1) to (S-4) thus prepared, as shown in Table 2.

P-1: The surface treatment agent was applied on the substrate by spin coating with a spin coater (“CLEAN TRACK ACTS,” available from Tokyo Electron Limited) at a rotation speed of 1,500 rpm, heated at 150° C. for 180 sec and cooled at 20° C. to 25° C. for 30 sec, and then a face on which the surface treatment agent had been applied was washed with propylene glycol monomethyl ether acetate for 30 sec at a rotation speed of 1,500 rpm.

P-2: The surface treatment agent was applied on the substrate by spin coating with the spin coater at a rotation speed of 1,500 rpm, and then a face on which the surface treatment agent had been applied was washed with propylene glycol monomethyl ether acetate for 30 sec at a rotation speed of 1,500 rpm.

P-3: The surface treatment agent was applied on the substrate by spin coating with the spin coater at a rotation speed of 1,500 rpm.

In all cases of the treatments (P-1) to (P-3), a film having an average thickness of 2 nm was formed from the surface treatment agent, on the surface of the substrate.

### Preparation of Resist Composition

A resist composition was prepared as in the following.

### Preparation Example 3-1

A resist composition (R-1) was obtained by mixing: 100 parts by mass of a polymer having a structural unit (1) derived from 4-hydroxystyrene, a structural unit (2) derived from styrene, and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; and as solvents, 4,400 parts by mass of ethyl lactate and 1,900 parts by mass of propylene glycol monomethyl ether acetate, and filtering a thus resulting solution through a filter having a pore size of 0.2 μm.

### Resist Pattern Forming

Development with Alkaline Developer Solution

### Examples 1-1 to 1-15 and Comparative Examples 1-1 to 1-17

The resist composition (R-1) was applied on the surface of each of the substrates having or not having been subjected to the treatment of the surface treatment agent-applying step as shown in Table 2 below, and heated at 130° C. for 60 sec, followed by cooling at 23° C. for 30 sec, to form a resist film having an average thickness of 50 nm. Next, the resist film was irradiated with an electron beam by using an electron beam writer (“HL800D,” available from Hitachi, Ltd.; output: 50 KeV; electric current density: 5.0 ampere/cm²). After the irradiation with the electron beam, the substrate was heated at 110° C. for 60 sec, followed by cooling at 23° C. for 60 sec. Thereafter, a development was carried out using a 2.38% by mass aqueous TMAH solution (20° C. to 25° C.) with a puddle procedure, followed by washing with water and drying to give a substrate for evaluation on which a resist pattern was formed. For line-width measurement and observation of the resist pattern on the substrate for evaluation, a scanning electron microscope (“S-9380,” available from Hitachi High-Technologies Corporation) was used.

### Evaluations

The sensitivity and the resolution were evaluated according to the following procedures. The results of the evaluations are shown in Table 2 below. In Table 2, “—” denotes that the treatment of the surface treatment agent-applying step was not carried out. Further, a basis for the evaluation of sensitivity is indicated by “—” in the “Sensitivity” column of the Comparative Example 1-11 in Table 2.

Sensitivity

Upon the resist pattern forming, an exposure dose at which a hole pattern with a diameter of 100 nm was formed was defined as an optimum exposure dose (1). With respect to the optimum exposure dose (1) in the case of the substrate (JF-2-6), the sensitivity was evaluated to be “A” (favorable) in a case of an increase in sensitivity being no less than 10% (in a case of the optimum exposure dose (1) of being no greater than 0.90 times); “B” (somewhat favorable) in a case of an increase in sensitivity being no less than 2% and less than 10% (in a case of the optimum exposure dose (1) being greater than 0.90 times and no greater than 0.98 times); and “C” (unfavorable) in a case of an increase in sensitivity being less than 2% or in a case of no increase in sensitivity (in a case of the optimum exposure dose (1) being greater than 0.98 times).

Resolution

Upon the resist pattern forming, an exposure dose at which a hole pattern with a diameter of 80 nm was formed was defined as an optimum exposure dose (2). On the hole pattern formed at the optimum exposure dose (2), the resolution was evaluated as: “A” (favorable) in a case of no resist film residue being identified; and “B” (unfavorable) in a case of resist film residue being identified.

TABLE 2

| | | | Surface | | |
|---|---|---|---|---|---|
| | | | treatment | | |
| | | Surface | agent- | | |
| | | treatment | applying | Sensi- | |
| | Substrate | agent | step | tivity | Resolution |
| Example 1-1 | JF-1-1 | S-1 | P-1 | A | A |
| Example 1-2 | JF-1-1 | S-2 | P-1 | A | A |
| Example 1-3 | JF-1-1 | S-3 | P-1 | A | A |
| Example 1-4 | JF-1-1 | S-3 | P-2 | A | A |
| Example 1-5 | JF-1-1 | S-4 | P-3 | A | A |
| Example 1-6 | JF-1-2 | S-1 | P-1 | A | A |
| Example 1-7 | JF-1-3 | S-1 | P-1 | A | A |
| Example 1-8 | JF-1-4 | S-1 | P-1 | A | A |
| Example 1-9 | JF-1-5 | S-1 | P-1 | B | A |
| Example 1-10 | JF-1-6 | S-1 | P-1 | A | A |
| Example 1-11 | JF-1-7 | S-1 | P-1 | A | A |
| Example 1-12 | JF-1-8 | S-1 | P-1 | A | A |
| Example 1-13 | JF-1-9 | S-1 | P-1 | A | A |
| Example 1-14 | JF-1-10 | S-1 | P-1 | A | A |
| Example 1-15 | JF-1-11 | S-1 | P-1 | A | A |
| Comparative | JF-1-1 | — | — | A | B |
| Example 1-1 | | | | | |
| Comparative | JF-1-2 | — | — | A | B |
| Example 1-2 | | | | | |
| Comparative | JF-1-3 | — | — | A | B |
| Example 1-3 | | | | | |
| Comparative | JF-1-4 | — | — | A | B |
| Example 1-4 | | | | | |
| Comparative | JF-1-5 | — | — | A | B |
| Example 1-5 | | | | | |
| Comparative | JF-2-1 | — | — | C | A |
| Example 1-6 | | | | | |
| Comparative | JF-2-2 | — | — | C | A |
| Example 1-7 | | | | | |
| Comparative | JF-2-3 | — | — | C | A |
| Example 1-8 | | | | | |
| Comparative | JF-2-4 | — | — | C | A |
| Example 1-9 | | | | | |
| Comparative | JF-2-5 | — | — | C | A |
| Example 1-10 | | | | | |
| Comparative | JF-2-6 | — | — | — | A |
| Example 1-11 | | | | | |
| Comparative | JF-1-6 | — | — | A | B |
| Example 1-12 | | | | | |
| Comparative | JF-1-7 | — | — | A | B |
| Example 1-13 | | | | | |
| Comparative | JF-1-8 | — | — | A | B |
| Example 1-14 | | | | | |
| Comparative | JF-1-9 | — | — | A | B |
| Example 1-15 | | | | | |
| Comparative | JF-1-10 | — | — | A | B |
| Example 1-16 | | | | | |
| Comparative | JF-1-11 | — | — | A | B |
| Example 1-17 | | | | | |

### Resist Pattern Forming

Development with Organic Solvent Developer Solution

### Examples 2-1 to 2-15 and Comparative Examples 2-1 to 2-17

The resist composition (R-1) was applied on the surface of each of the substrates having or not having been subjected to the treatment of the surface treatment agent-applying step as shown in Table 3 below, and heated at 130° C. for 60 sec, followed by cooling at 23° C. for 30 sec, to form a resist film having an average thickness of 50 nm. Next, the resist film was irradiated with an electron beam by using an electron beam writer (“HL800D,” available from Hitachi, Ltd.; output: 50 KeV; electric current density: 5.0 ampere/cm²). After the irradiation with the electron beam, the substrate was heated at 110° C. for 60 sec, followed by cooling at 23° C. for 60 sec. Thereafter, a development was carried out using butyl acetate (20° C. to 25° C.) with a puddle procedure, followed by drying to give a substrate for evaluation on which a resist pattern was formed. For line-width measurement and observation of the resist pattern on the substrate for evaluation, a scanning electron microscope (“S-9380,” available from Hitachi High-Technologies Corporation) was used.

### Evaluations

The sensitivity and a resist pattern collapse-inhibiting property were evaluated according to the following procedures. The results of the evaluations are shown in Table 3 below. In Table 3, “—” denotes that the treatment of the surface treatment agent-applying step was not carried out. Further, a basis for the evaluation of sensitivity is indicated by “—” in the “Sensitivity” column of the Comparative Example 2-11 in Table 3.

Sensitivity

Upon the resist pattern forming, an exposure dose at which a 1:1 line-and-space with a line width of 150 nm was formed was defined as an optimum exposure dose (3). With respect to the optimum exposure dose (3) in the case of the substrate (JF-2-6), the sensitivity was evaluated to be: “A” (favorable) in a case of an increase in sensitivity being no less than 10% (in a case of the optimum exposure dose (3) of being no greater than 0.9 times); “B” (slightly favorable) in a case of an increase in sensitivity being no less than 2% and less than 10% (in a case of the optimum exposure dose (3) being greater than 0.90 times and no greater than 0.98 times); and “C” (unfavorable) in a case of an increase in sensitivity being less than 2% or in a case of no increase in sensitivity (in a case of the optimum exposure dose (3) being greater than 0.98 times).

Resist Pattern Collapse-Inhibiting Property

Upon the resist pattern forming, an exposure dose at which a 1:1 line-and-space with a line width of 100 nm was formed was defined as an optimum exposure dose (4). The resist pattern collapse-inhibiting property was evaluated as: “A” (favorable) in a case of no collapse being identified; and “B” (unfavorable) in a case of collapse being identified, with regard to the resist pattern formed at the optimum exposure dose (4).

TABLE 3

| | | | Surface | | Collapse- |
|---|---|---|---|---|---|
| | | | treatment | | inhibiting |
| | | Surface | agent- | | property |
| | | treatment | applying | Sensi- | of resist |
| | Substrate | agent | step | tivity | pattern |
| Example 2-1 | JF-1-1 | S-1 | P-1 | A | A |
| Example 2-2 | JF-1-1 | S-2 | P-1 | A | A |
| Example 2-3 | JF-1-1 | S-3 | P-1 | A | A |
| Example 2-4 | JF-1-1 | S-3 | P-2 | A | A |
| Example 2-5 | JF-1-1 | S-4 | P-3 | A | A |
| Example 2-6 | JF-1-2 | S-1 | P-1 | A | A |
| Example 2-7 | JF-1-3 | S-1 | P-1 | A | A |
| Example 2-8 | JF-1-4 | S-1 | P-1 | A | A |
| Example 2-9 | JF-1-5 | S-1 | P-1 | B | A |
| Example 2-10 | JF-1-6 | S-1 | P-1 | A | A |
| Example 2-11 | JF-1-7 | S-1 | P-1 | A | A |
| Example 2-12 | JF-1-8 | S-1 | P-1 | A | A |
| Example 2-13 | JF-1-9 | S-1 | P-1 | A | A |
| Example 2-14 | JF-1-10 | S-1 | P-1 | A | A |
| Example 2-15 | JF-1-11 | S-1 | P-1 | A | A |
| Comparative | JF-1-1 | — | — | A | B |
| Example 2-1 | | | | | |
| Comparative | JF-1-2 | — | — | A | B |
| Example 2-2 | | | | | |
| Comparative | JF-1-3 | — | — | A | B |
| Example 2-3 | | | | | |
| Comparative | JF-1-4 | — | — | A | B |
| Example 2-4 | | | | | |
| Comparative | JF-1-5 | — | — | A | B |
| Example 2-5 | | | | | |
| Comparative | JF-2-1 | — | — | C | A |
| Example 2-6 | | | | | |
| Comparative | JF-2-2 | — | — | C | A |
| Example 2-7 | | | | | |
| Comparative | JF-2-3 | — | — | C | A |
| Example 2-8 | | | | | |
| Comparative | JF-2-4 | — | — | C | A |
| Example 2-9 | | | | | |
| Comparative | JF-2-5 | — | — | C | A |
| Example 2-10 | | | | | |
| Comparative | JF-2-6 | — | — | — | A |
| Example 2-11 | | | | | |
| Comparative | JF-1-6 | — | — | A | B |
| Example 2-12 | | | | | |
| Comparative | JF-1-7 | — | — | A | B |
| Example 2-13 | | | | | |
| Comparative | JF-1-8 | — | — | A | B |
| Example 2-14 | | | | | |
| Comparative | JF-1-9 | — | — | A | B |
| Example 2-15 | | | | | |
| Comparative | JF-1-10 | — | — | A | B |
| Example 2-16 | | | | | |
| Comparative | JF-1-11 | — | — | A | B |
| Example 2-17 | | | | | |

As is clear from the results shown in Tables 2 and 3, according to the substrate-producing method of the Examples, a resist pattern superior in resolution and the collapse-inhibiting property can be formed in a highly sensitive manner. In contrast, the substrate-producing method of the Comparative Examples failed to achieve both of a high sensitivity, and a superior resolution and a superior collapse-inhibiting property of the resist pattern. According to the substrate-producing method of the Examples, it is considered that use of the favorable resist pattern formed, which was superior in resolution and the collapse-inhibiting property, enabled a favorable substrate pattern to be obtained. It is to be noted that a resist pattern upon electron beam exposure is generally known to have a tendency similar to that of a resist pattern upon exposure to an extreme ultraviolet ray or an electron beam. Thus, it is presumed that according to the substrate-producing method of the Examples, also in a case of the exposure to the extreme ultraviolet ray or the electron beam, lithography can be carried out in a highly sensitive manner, a resist pattern superior in resolution and the collapse-inhibiting property can be formed, and in turn a favorable substrate pattern can be obtained.

The patterned substrate-producing method of the embodiment of the present invention enables extreme ultraviolet lithography or electron beam lithography to be carried out in a highly sensitive manner, a resist pattern superior in resolution and the collapse-inhibiting property to be obtained, and in turn a favorable substrate pattern to be obtained. Accordingly, the patterned substrate-producing method can be suitably used for extreme ultraviolet lithography or electron beam lithography, as well as for manufacture of semiconductor devices, for which microfabrication is expected to progress further hereafter, and the like.

Obviously, numerous modifications and variations of the present invention are possible in light of the above teachings. It is therefore to be understood that within the scope of the appended claims, the invention may be practiced otherwise than as specifically described herein.

What is claimed is:

1. A patterned substrate-producing method comprising:
applying a surface treatment agent on a surface layer of a substrate, the surface layer comprising at least one metal element;
applying a resist composition on a surface of the surface layer to provide a resist film on the surface;
exposing the resist film to an extreme ultraviolet ray or an electron beam;
developing the resist film exposed to form a resist pattern; and
etching the substrate using the resist pattern as a mask,
wherein the surface treatment agent comprises: a polymer comprising a group comprising a polar group at at least one end of a main chain of the polymer; and a solvent.

2. The patterned substrate-producing method according to claim 1, wherein the at least one metal element in the surface layer of the substrate belongs to period 3 to period 7 of group 3 to group 15 in periodic table.

3. The patterned substrate-producing method according to claim 2, wherein the at least one metal element belongs to group 4 in the periodic table.

4. The patterned substrate-producing method according to claim 3, wherein the at least one metal element is titanium, zirconium, or a combination thereof.

5. The patterned substrate-producing method according to claim 1, wherein the polar group in the polymer is a hydroxy group, a carboxy group, a sulfo group, a sulfanyl group, a silanol group, or a combination thereof.

6. The patterned substrate-producing method according to claim 1, wherein the polymer comprises an aromatic carbocyclic ring.

7. The patterned substrate-producing method according to claim 1, wherein the polymer comprises a structural unit derived from a substituted or unsubstituted styrene, a structural unit derived from a substituted or unsubstituted ethylene, or both.

8. The patterned substrate-producing method according to claim 1, wherein the substrate comprises:
a base;
an organic underlayer film formed directly or indirectly on at least an upper face of the base; and
a metal-containing layer formed directly or indirectly on an upper face of the organic underlayer film.

9. The patterned substrate-producing method according to claim 4, wherein the polar group in the polymer is a hydroxy group.

10. The patterned substrate-producing method according to claim 9, wherein the polymer comprises an aromatic carbocyclic ring.

11. The patterned substrate-producing method according to claim 9, wherein the polymer comprises a structural unit derived from a substituted or unsubstituted styrene, a structural unit derived from a substituted or unsubstituted ethylene, or both.

12. The patterned substrate-producing method according to claim 11, wherein the substrate comprises:
a base;
an organic underlayer film formed directly or indirectly on at least an upper face of the base; and
a metal-containing layer formed directly or indirectly on an upper face of the organic underlayer film.

13. The patterned substrate-producing method according to claim 5, wherein the at least one metal element is titanium, zirconium, or a combination thereof.

14. The patterned substrate-producing method according to claim 13, wherein the polymer comprises an aromatic carbocyclic ring.

15. The patterned substrate-producing method according to claim 13, wherein the polymer comprises a structural unit derived from a substituted or unsubstituted styrene, a structural unit derived from a substituted or unsubstituted ethylene, or both.

16. The patterned substrate-producing method according to claim 15, wherein the substrate comprises:
a base;
an organic underlayer film formed directly or indirectly on at least an upper face of the base; and
a metal-containing layer formed directly or indirectly on an upper face of the organic underlayer film.
